(19) United States
(12) Patent Application Publication
(10) Pub. No.: US 2024/0228800 A1
(43) Pub. Date: Jul. 11, 2024

(54) COATING MATERIAL, COATING LAYER, AND LIGHT-EMITTING DEVICE

(71) Applicant: INDUSTRIAL TECHNOLOGY RESEARCH INSTITUTE, Hsinchu (TW)

(72) Inventors: Hsiang-Jui CHEN, Hsinchu City (TW); Chih-Hao LIN, Taoyuan City (TW); Yueh-Chuan HUANG, Zhudong Township (TW)

(73) Assignee: INDUSTRIAL TECHNOLOGY RESEARCH INSTITUTE, Hsinchu (TW)

(21) Appl. No.: 18/497,157

(22) Filed: Oct. 30, 2023

Related U.S. Application Data
(63) Continuation-in-part of application No. 18/146,012, filed on Dec. 23, 2022, now abandoned.

(30) Foreign Application Priority Data
Jul. 18, 2023 (TW) 112126660

(51) Int. Cl. C09D 7/62; C08G 59/22; C08G 59/30; C08K 9/06; C09D 163/00; H01L 33/56; H01L 33/58

(52) U.S. Cl. CPC C09D 7/62; C08G 59/226; C08G 59/306; C08K 9/06; C09D 163/00; H01L 33/56; H01L 33/58

(57) ABSTRACT

A coating material includes a modified particle and a reactive compound. The modified particle includes a core, and a silane coupling agent having an epoxy group (or a double-bond) grafted onto a surface of the core. When the silane coupling agent having the epoxy group is grafted onto the surface of the core, the reactive compound includes a non-silicon multi-epoxy compound and a silicon-containing multi-epoxy compound. When the silane coupling agent having the double-bond is grafted onto the surface of the core, the reactive compound includes a multi double-bond compound.

### CROSS REFERENCE TO RELATED APPLICATIONS

This application is a Continuation-In-Part of pending U.S. patent application Ser. No. 18/146,012, filed on Dec. 23, 2022 and entitled “Coating material, coating layer, and light-emitting device”. This application claims priority of Taiwan Patent Application No. 112126660, filed on Jul. 18, 2023, the entirety of which is incorporated by reference herein.

### TECHNICAL FIELD

The technical field relates to a coating material, a coating layer and a light-emitting device.

### BACKGROUND

It is difficult for an organic polymer to form a film with a high refractive index. An inorganic material can form a film with a high refractive index, but it encounters processing difficulties in certain applications. Therefore, an inorganic material cannot form a film with an adequate thickness. Accordingly, it is necessary to design a novel film composition able to manufacture a film with a high refractive index and an adequate thickness.

### SUMMARY

One embodiment of the disclosure provides a coating material including a modified particle. The modified particle includes a core and a silane coupling agent. The silane coupling agent has an epoxy group or a double-bond grafted onto the surface of the core. The core includes (1) an oxide of zinc and titanium, and zinc and titanium have a weight ratio of 1:0.4 to 1:0.9, (2) an oxide of zirconium and titanium, and zirconium and titanium have a weight ratio of 1:0.1 to 1:2, or (3) an oxide of zinc and zirconium, and zinc and zirconium have a weight ratio of 1:0.8 to 1:2. The coating material also includes a reactive compound. When the silane coupling agent having the epoxy group is grafted onto the surface of the core, the reactive compound includes a non-silicon multi-epoxy compound and a silicon-containing multi-epoxy compound. When the silane coupling agent having the double-bond is grafted onto the surface of the core, the reactive compound includes a multi double-bond compound.

One embodiment of the disclosure provides a coating layer formed by reacting the described coating material.

One embodiment of the disclosure provides a light-emitting device including a substrate; a light-emitting element disposed on the substrate; and the described coating layer covering the substrate and the light-emitting element.

A detailed description is given in the following embodiments.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details.

One embodiment of the disclosure provides a coating material, including a modified particle and a reactive compound. The modified particle includes a core and a silane coupling agent. The silane coupling agent has an epoxy group or a double-bond grafted onto the surface of the core. The core includes (1) an oxide of zinc and titanium, (2) an oxide of zirconium and titanium, or (3) an oxide of zinc and zirconium. When the core includes (1) the oxide of zinc and titanium, zinc and titanium have a weight ratio of 1:0.4 to 1:0.9. If the zinc amount is too much, the core will easily precipitate during the reaction, and a stable crystal state of the core will not be easily kept. If the titanium amount is too much, the core will quickly gel during the reaction and cannot be used. When the core includes (2) the oxide of zirconium and titanium, zirconium and titanium have a weight ratio of 1:0.1 to 1:2. If the titanium amount is too much, the color will be deep yellow and cannot keep a high light-transmittance and low b* value at the visible light band. When the core includes (3) the oxide of zinc and zirconium, zinc and zirconium have a weight ratio of 1:0.8 to 1:2. In some embodiments, zinc and zirconium have a weight ratio of 1:0.8 to 1:1.8. If the zinc amount is too much, the core will easily precipitate during the reaction. If the zirconium amount is too much, the reaction will be gelled by overly bonding.

When the silane coupling agent having the epoxy group is grafted onto the surface of the core, the reactive compound includes a non-silicon multi-epoxy compound and a silicon-containing multi-epoxy compound. When the silane coupling agent having the double-bond is grafted onto the surface of the core, the reactive compound includes a multi double-bond compound.

In one embodiment, the core is formed by hydrolyzing a zinc source to form zinc oxide, and then condensing with a titanium source. The core mainly includes zinc, titanium, and oxygen (e.g. oxide of zinc and titanium). The surface of the core includes a plurality of hydroxy groups and alkoxy groups. Note that the core is the oxide of zinc and titanium, other than a mixture of zinc oxide and titanium oxide (e.g. the titanium of the titanium oxide and the oxygen of the zinc oxide have no bonding therebetween, and the oxygen of the titanium oxide and the zinc of the zinc oxide have no bonding therebetween). Compared to the core of the oxide of zinc and titanium, the core of the mixture of the zinc oxide and the titanium oxide will precipitate as a solid. Subsequently, a silane coupling agent having an epoxy group or a silane coupling agent having a double-bond is reacted with the core, such that the Si—O-alkyl group of the silane is reacted with the —OR group (R═H or alkyl) on the surface of the core to form Zn/Ti—O—Si bonding, such that the silane coupling agent is grafted onto the surface of the core. Note that the above reaction is one way and not the only way to form the modified particle. One skilled in the art may adopt suitable reactants to form the described modified particle.

In one embodiment, the core is formed by condensing a zirconium source and a titanium source. The core mainly includes zirconium, titanium, and oxygen (e.g. oxide of zirconium and titanium). The surface of the core includes a plurality of hydroxy groups and alkoxy groups. Note that the core is the oxide of zirconium and titanium, other than a mixture of zirconium oxide and titanium oxide (e.g. the titanium of the titanium oxide and the oxygen of the zirconium oxide have no bonding therebetween, and the oxygen of the titanium oxide and the zirconium of the zirconium oxide have no bonding therebetween). Compared to the core of the oxide of zirconium and titanium, the core of the mixture of the zirconium oxide and the titanium oxide will precipitate as a solid. Subsequently, a silane coupling agent having an epoxy group or a silane coupling agent having a double-bond is reacted with the core, such that the Si—O-alkyl group of the silane is reacted with the —OR group (R═H or alkyl) on the surface of the core to form Zr/Ti—O—Si bonding, such that the silane coupling agent is grafted onto the surface of the core. Note that the above reaction is one way and not the only way to form the modified particle. One skilled in the art may adopt suitable reactants to form the described modified particle.

In one embodiment, the core is formed by hydrolyzing a zinc source to form zinc oxide, and then condensing with a zirconium source. The core mainly includes zinc, zirconium, and oxygen (e.g. oxide of zinc and zirconium). The surface of the core includes a plurality of hydroxy groups and alkoxy groups. Note that the core is the oxide of zinc and zirconium, other than a mixture of zinc oxide and zirconium oxide (e.g. the zinc of the zinc oxide and the oxygen of the zirconium oxide have no bonding therebetween, and the oxygen of the zinc oxide and the zirconium of the zirconium oxide have no bonding therebetween). Compared to the core of the oxide of zinc and zirconium, the core of the mixture of the zinc oxide and the zirconium oxide will precipitate as a solid. Subsequently, a silane coupling agent having an epoxy group or a silane coupling agent having a double-bond is reacted with the core, such that the Si—O-alkyl group of the silane is reacted with the —OR group (R═H or alkyl) on the surface of the core to form Zn/Zr—O—Si bonding, such that the silane coupling agent is grafted onto the surface of the core. Note that the above reaction is one way and not the only way to form the modified particle. One skilled in the art may adopt suitable reactants to form the described modified particle.

In some embodiments, the zinc source can be zinc acetate, zinc perchlorate, or zinc bromide. In some embodiments, the titanium source can be titanium isopropoxide, titanium tetrachloride, or titanium butoxide. In some embodiments, the zirconium source can be zirconium n-propoxide, zirconium isopropoxide, or zirconium tetrachloride.

In some embodiments, the total weight of zinc and titanium in the core and the weight of the silane coupling agent having the epoxy group (or the silane coupling agent having the double-bond) have a ratio of 1:0.1 to 1:3, such as 1:0.1 to 1:1.5. In some embodiments, the total weight of zirconium and titanium in the core and the weight of the silane coupling agent having the epoxy group (or the silane coupling agent having the double-bond) have a ratio of 1:0.1 to 1:3, or 1:0.1 to 1:1.5. In some embodiments, the total weight of zinc and zirconium in the core and the weight of the silane coupling agent having the epoxy group (or the silane coupling agent having the double-bond) have a ratio of 1:0.1 to 1:3, or 1:0.1 to 1:1.5. If the amount of silane coupling agent is too low, the coating layer cannot be formed. If the amount of silane coupling agent is too high, the refractive index of the coating layer will be insufficient (e.g. less than 1.7).

In some embodiments, the core has an average diameter of 10 nm to 120 nm, such as 15 nm to 55 nm. If the average diameter of the core is too small, it will be difficult to form a coating layer with a high refractive index. If the average diameter of the core is too large, the light-transmittance of the coating layer will be less than 90% and the light extraction efficiency cannot be enhanced.

In some embodiments, the silane coupling agent having the epoxy group includes (3-glycidyloxypropyl)trimethoxysilane, (3-glycidyloxypropyl)triethoxysilane, (3-glycidyloxypropyl)dimethoxymethylsilane, (3-glycidyloxypropyl)diethoxymethylsilane, β-(3,4-epoxycyclohexane)ethyl trimethoxysilane, or β-(3,4-epoxycyclohexane)ethyl triethoxysilane.

In some embodiments, the silane coupling agent having the double-bond includes 3-(trimethoxysilyl)propyl acrylate, 3-isocyanatopropyltriethoxysilane, or

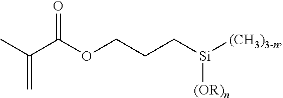

wherein R is methyl or ethyl, and n is 1-3.

In some embodiments, the core and the reactive compound have a weight ratio of 1:0.2 to 1:0.8. If the amount of reactive compound is too low, the coating layer will be split. If the amount of reactive compound is too high, the refractive index of the coating layer will be insufficient.

In some embodiments, the non-silicon multi-epoxy compound and the silicon-containing multi-epoxy compound have a weight ratio of 1:0.4 to 1:1. If the amount of non-silicon multi-epoxy compound is too low, the coating layer will be split. If the amount of non-silicon multi-epoxy compound is too high, the light-transmittance of the coating layer will be insufficient.

In some embodiments, the non-silicon multi-epoxy compound includes a long carbon chain, a benzene ring, or a cyclic structure, and the non-silicon multi-epoxy compound has a viscosity of less than 1000 cP at 25° ° C. For example, the non-silicon multi-epoxy compound includes

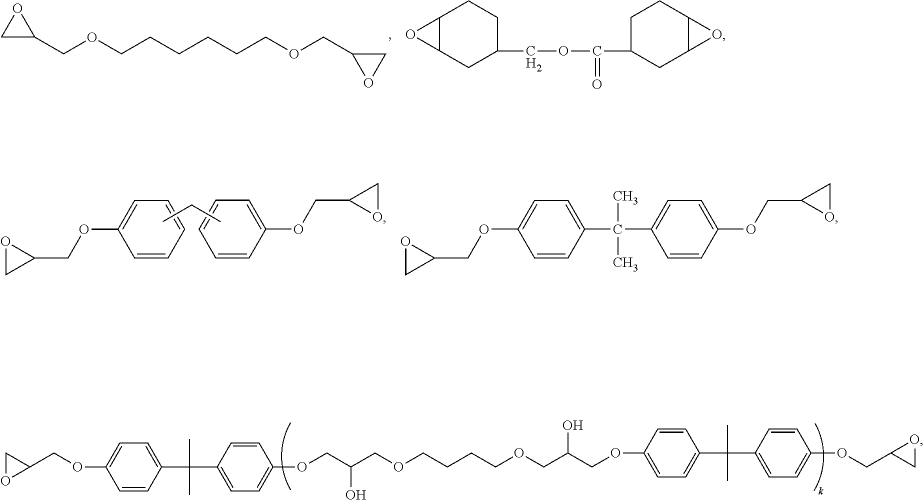

wherein k=1 to 6, or a combination thereof.

In some embodiments, the silicon-containing multi-epoxy compound includes a long carbon chain, a benzene ring, or a cyclic structure, and the silicon-containing multi-epoxy compound has a viscosity of less than 1000 cP at 25° C. For example the silicon-containing multi-epoxy compound includes

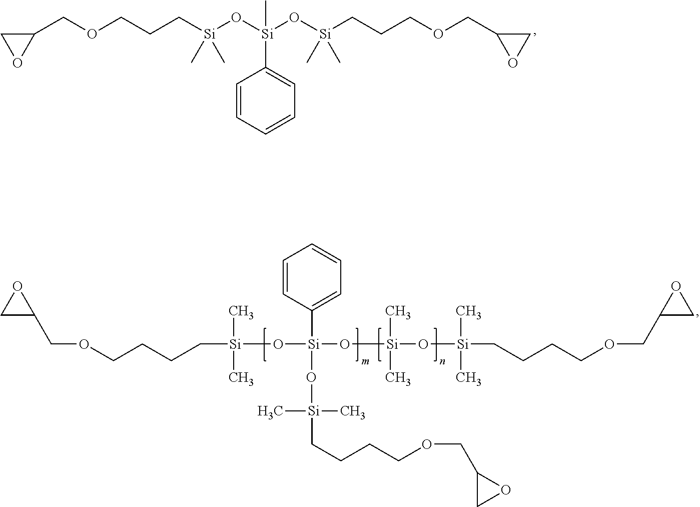

wherein m=1 to 6 and n=1 to 6,

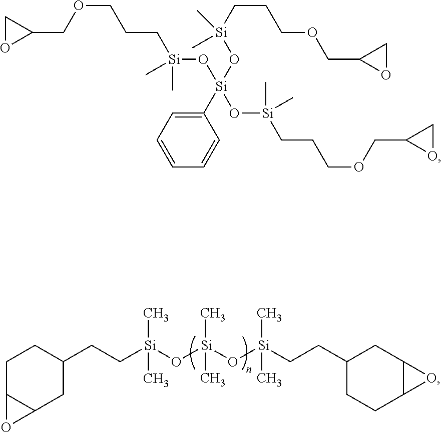

wherein n=1 to 6, or a combination thereof.

In some embodiments, the multi double-bond compound includes a long carbon chain, a benzene ring, or a cyclic structure, and the multi double-bond compound has a viscosity of less than 1000 cP at 25° C. For example, the multi double-bond compound includes

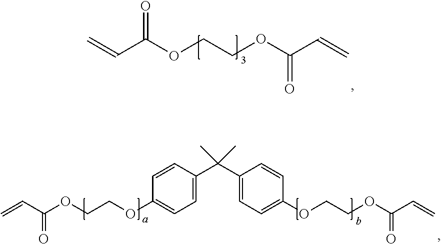

wherein a=2 to 6 and b=2 to 6, or a combination thereof.

One embodiment of the disclosure provides a coating layer formed by reacting the described coating material. For example, if the silane coupling agent having an epoxy group is grafted onto the core surface of the modified particles in the coating material, and the corresponding reactive compound includes the non-silicon multi-epoxy compound and the silicon-containing multi-epoxy compound, the coating material may further include a catalytic amount of crosslinker. The crosslinker may ring-open the epoxy groups to achieve the crosslinking effect. In some embodiments, the coating material and the crosslinker have a weight ratio of 1:0.09 to 1:0.13. If the amount of crosslinker is too low, the coating material may not crosslink to form a film during the reaction. If the amount of crosslinker is too high, the refractive index of the coating layer will be lowered. In some embodiments, the crosslinker is C₂-C₆ amine compound, C₂-C₆ alcohol compound, or C₂-C₆ acid compound. In some embodiments, the crosslinker is HO—(CH₂)ₙ—NH₂, and n is 2 to 4. For example, if the silane coupling agent having a double-bond is grafted onto the core surface of the modified particles in the coating material, and the corresponding reactive compound includes the multi double-bond compound, the coating material may further include a catalytic amount of radical initiator. For example, the coating material and the radical initiator may have a weight ratio of 1:0.09 to 1:0.13. The radical initiator can be a thermal initiator or photo initiator, which may generate radicals after being irradiated or heated to crosslink the double-bonds of the silane coupling agent and the multi double-bond compound.

In some embodiments, the coating material can be blade coated or spin coated onto a substrate, and the substrate may include any active element or passive element therein or thereon. The coating material is then cured to form a coating layer. In some embodiments, the coating layer has a thickness of 20 micrometers to 40 micrometers, a refractive index of 1.7 to 2.4, and a light-transmittance of 90% to 99.5%. If the thickness of the coating layer is too thin, the coating layer cannot efficiently protect the active element or passive element that is covered by the coating layer. If the refractive index of the coating layer is too low, the light loss caused by the refractive index difference cannot be avoided when the coating layer covers an element of high refractive index (such as a micro light-emitting diode). If the light-transmittance of the coating layer is too low, the coating layer cannot serve as a transparent protective layer (e.g. a protective layer for covering the light-emitting element).

One embodiment of the disclosure provides a light-emitting device including a substrate; a light-emitting element disposed on the substrate; and the described coating layer covering the substrate and the light-emitting element. The coating layer of the disclosure may efficiently protect the light-emitting element due to its sufficient thickness, refractive index, and light-transmittance. In some embodiments, the light-emitting element can be a light-emitting diode such as an organic light-emitting diode, an inorganic light-emitting diode, or another suitable light-emitting diode. The refractive index of the material in the light-emitting element is often greater than 2. If the refractive index of the film covering the light-emitting element is too small (e.g. less than 1.7), the refractive index difference will result in a light loss. Note that the coating layer of the disclosure is mainly applied to protect the light-emitting element in the light-emitting device, it should be understood that the coating layer can protect any element other than the light-emitting element (and is not limited to the light-emitting device).

Accordingly, the organic-inorganic composite coating material of the disclosure may form a film with high refractive index, an adequate thickness, high light-transmittance and high thermal resistance. Through designing the composite material, the refractive index can be tuned and the high light-transmittance can be kept, and the thickness of the coating layer can be further increased. In short, the disclosed coating material for the coating layer has high light-transmittance, high refractive index, and thick thickness to achieve the effect of protecting the element (e.g. the light-emitting diode of high refractive index).

Below, exemplary embodiments will be described in detail with reference to accompanying drawings so as to be easily realized by a person having ordinary knowledge in the art. The inventive concept may be embodied in various forms without being limited to the exemplary embodiments set forth herein. Descriptions of well-known parts are omitted for clarity.

### EXAMPLES

In following Examples, the light-transmittance of the coating layer was measured with a UV/VIS spectrophotometer, in which the wavelength of 450 nm was set as the reference to measure the light-transmittance value. The refractive index of the coating layer was measured with a thin film analyzer (N & K analyzer). The average diameter of the core particles was measured with a multi-sample nanoparticle size measurement system (Otsuka nanoSAQLA), in which the measurement range was 0.6 nm to 10 μm with an accuracy of ±2%. In following Examples, the viscosity was measured according to the standard ASTM D1084 by Brookfield Viscometer DV-III Ultra.

### Synthesis Example 1

5 g of zinc acetate, 20 g of isopropanol, and 1.9 g of ethanolamine were heated to 80° C. to be dissolved and reacted for 5 minutes. Subsequently, 10 g of titanium isopropoxide and 0.25 g of isopentanedione were added to the reaction mixture, and further reacted at 80° ° C. for 8 hours to form core particles. The core particles included an oxide of zinc and titanium, and zinc and titanium had a weight ratio of 1:0.6, 2.2 g of (3-glycidyloxypropyl)trimethoxysilane was then added to perform a surface modification. The total weight of zinc and titanium in the core particles and the weight of (3-glycidyloxypropyl)trimethoxysilane had a ratio of 1:0.15. The Si—O—CH₃ of the silane and the —OR (R═H or CH(CH₃)₂) on the surface of the core particles could react to form Zn/Ti—O—Si bonding, such as the silane being grafted onto the surface of the core particles to form a dispersion of modified particles, and the core particles had an average diameter of 80 nm.

### Synthesis Example 2

5 g of zinc acetate, 20 g of isopropanol, and 1.9 g of ethanolamine were heated to 80° ° C. to be dissolved and reacted for 5 minutes. Subsequently, 10 g of titanium isopropoxide and 0.25 g of isopentanedione were added to the reaction mixture, and further reacted at 80° C. for 8 hours to form core particles. The core particles included an oxide of zinc and titanium, and zinc and titanium had a weight ratio of 1:0.6, 2.2 g of (3-glycidyloxypropyl)trimethoxysilane was then added to perform a surface modification. The total weight of zinc and titanium in the core particles and the weight of (3-glycidyloxypropyl)trimethoxysilane had a ratio of 1:0.15. The Si—O—CH₃ of the silane and the —OR (R═H or CH(CH₃)₂) on the surface of the core particles could react to form Zn/Ti—O—Si bonding, such as the silane being grafted onto the surface of the core particles to form a dispersion of modified particles, and the core particles had an average diameter of 80 nm. Finally, the isopropanol in the dispersion was replaced with toluene.

### Synthesis Example 3

15 g of zirconium n-propoxide, 15 g of titanium isopropoxide, 20 g of isopropanol, and 0.25 g of isopentanedione were reacted at 80° C. for 8 hours to form core particles. The core particles included an oxide of zirconium and titanium, and zirconium and titanium had a weight ratio of 1:0.9, 3 g of (3-glycidyloxypropyl)trimethoxysilane was then added to perform a surface modification. The total weight of zirconium and the titanium in the core particles and the weight of (3-glycidyloxypropyl)trimethoxysilane had a ratio of 1:0.1. The Si—O—CH₃ of the silane and the —OR (R═H or CH(CH₃)₂) on the surface of the core particles could react to form Zr/Ti—O—Si bonding, such as the silane being grafted onto the surface of the core particles to form a dispersion of modified particles, and the core particles had an average diameter of 40 nm.

### Synthesis Example 4

5 g of zinc acetate, 20 g of isopropanol, and 1.9 g of ethanolamine were heated to 80° C. to be dissolved and reacted for 5 minutes. Subsequently, 10 g of titanium isopropoxide and 0.25 g of isopentanedione were added to the reaction mixture, and further reacted at 80° C. for 8 hours to form core particles. The core particles included an oxide of zinc and titanium, and zinc and titanium had a weight ratio of 1:0.6, 2.2 g of 3-(trimethoxysilyl)propyl acrylate was then added to perform a surface modification. The total weight of zinc and titanium in the core particles and the weight of 3-(trimethoxysilyl)propyl acrylate had a ratio of 1:0.15. The Si—O—CH₃ of the silane and the —OR (R═H or CH(CH₃)₂) on the surface of the core particles could react to form Zn/Ti—O—Si bonding, such as the silane being grafted onto the surface of the core particles to form a dispersion of modified particles, and the core particles had an average diameter of 75 nm.

### Synthesis Example 5

5 g of zinc acetate, 20 g of isopropanol, and 0.48 M of KOH (3 mL) were heated to 80° C. to be dissolved and reacted for 5 minutes. Subsequently, 10 g of zirconium n-propoxide was added to the reaction mixture, and further reacted at 80° C. for 8 hours to form core particles. The core particles included an oxide of zinc and zirconium, and zinc and zirconium had a weight ratio of 1:1.8, 2.2 g of (3-glycidyloxypropyl)trimethoxysilane was then added to perform a surface modification. The total weight of zinc and zirconium in the core particles and the weight of (3-glycidyloxypropyl)trimethoxysilane had a ratio of 1:0.15. The Si—O—CH₃ of the silane and the —OR (R═H or CH(CH₃)₂) on the surface of the core particles could react to form Zn/Zr—O—Si bonding, such as the silane being grafted onto the surface of the core particles to form a dispersion of modified particles, and the core particles had an average diameter of 79 nm.

### Verification Example

0.25 g of a silicon-containing multi-epoxy compound GT1250 (commercially available from GRAND-TEK ADVANCE MATERIAL SCIENCE CO., LTD., having a chemical structure of

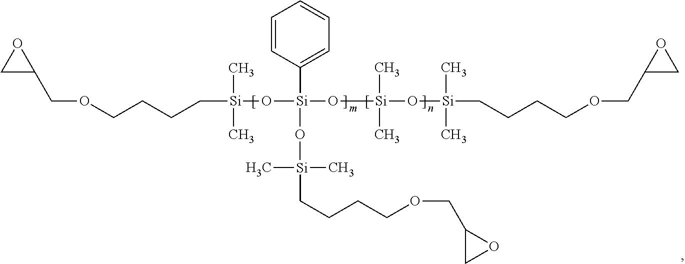

wherein

m=1 to 6 and n=1 to 6) and the dispersion containing 1 g of the modified particles in Synthesis Example 1 were blended to keep a solution without phase separation and precipitation. Accordingly, the silicon-containing multi-epoxy compound GT1250 was compatible with the modified particles. The solution was coated and baking cured (baked at 80° C. for 10 minutes and baked at 120° C. for 10 minutes) to form a dry film with a thickness of 5 micrometers. Accordingly, GT1250 could serve as the reactive compound.

0.25 g of a silicon-containing multi-epoxy compound ESP-EDTP0204 (self-synthesized, having a chemical structure of

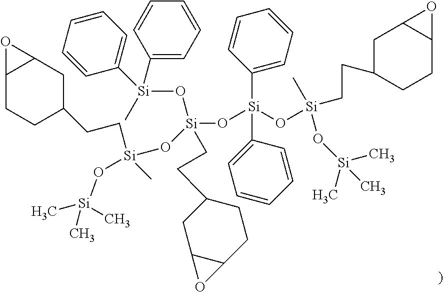 [SMILES: C[Si](C)(C)O[Si](C)(CCC1CCC2OC2C1)O[Si](CCC1CCC2OC2C1)(O[Si](C)(c1ccccc1)c1ccccc1)O[Si](O[Si](C)(CCC1CCC2OC2C1)O[Si](C)(C)C)(c1ccccc1)c1ccccc1]

and the dispersion containing 1 g of the modified particles in Synthesis Example 1 were blended to generate phase separation or precipitation. 0.25 g of the silicon-containing multi-epoxy compound ESP-EDTP0204 and the dispersion containing 1 g of the modified particles in Synthesis Example 2 were blended to generate phase separation or precipitation. Accordingly, the silicon-containing multi-epoxy compound ESP-EDTP0204 was not compatible with the modified particles. Accordingly, ESP-EDTP0204 could not serve as the reactive compound.

0.25 g of a silicon-containing multi-epoxy compound SIT8715.6 (commercially available from Gelest, having a chemical structure of

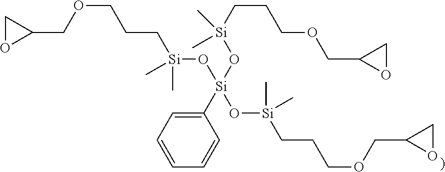 [SMILES: C[Si](C)(CCCOCC1CO1)O[Si](O[Si](C)(C)CCCOCC1CO1)(O[Si](C)(C)CCCOCC1CO1)c1ccccc1]

and the dispersion containing 1 g of the modified particles in Synthesis Example 1 were blended to keep a solution without phase separation and precipitation. Accordingly, the silicon-containing multi-epoxy compound SIT8715.6 was compatible with the modified particles. The solution was coated and baking cured (baked at 80° C. for 10 minutes and baked at 120° C. for 10 minutes) to form a dry film with a thickness of 5 micrometers. Accordingly, SIT8715.6 could serve as the reactive compound.

0.25 g of a silicon-containing multi-epoxy compound SIT7281.5 (commercially available from Gelest, having a chemical structure of

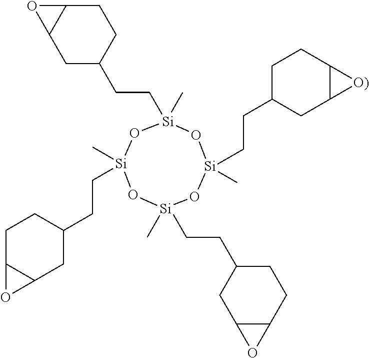

and the dispersion containing 1 g of the modified particles in Synthesis Example 1 were blended to keep a solution without phase separation and precipitation. 0.25 g of a silicon-containing multi-epoxy compound SIT7281.5 and the dispersion containing 1 g of the modified particles in Synthesis Example 2 were blended to keep a solution without phase separation and precipitation. Accordingly, the silicon-containing multi-epoxy compound SIT7281.5 was compatible with the modified particles. However, the solutions could not be coated and baking cured (baked at 80° C. for 10 minutes and baked at 120° C. for 10 minutes) to form a dry film with a thickness of 5 micrometers. Accordingly, SIT7281.5 could not serve as the reactive compound.

0.25 g of a non-silicon multi-epoxy compound YX7400 (commercially available from Mitsubishi Chemical Corporation, having a chemical structure of

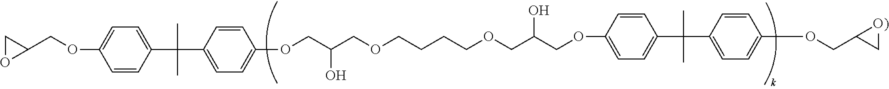

and the dispersion containing 1 g of the modified particles in Synthesis Example 1 were blended to keep a solution without phase separation and precipitation. Accordingly, the non-silicon multi-epoxy compound YX7400 was compatible with the modified particles. The solution was coated and baking cured (baked at 80° C. for 10 minutes and baked at 120° C. for 10 minutes) to form a dry film with a thickness of 5 micrometers. Accordingly, YX7400 could serve as the reactive compound.

0.25 g of a non-silicon multi-epoxy compound 412P (commercially available from Double Bond Chemical Ind. Co., Ltd., having a chemical structure of

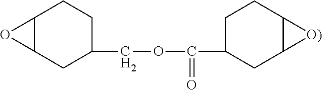

and the dispersion containing 1 g of the modified particles in Synthesis Example 1 were blended to keep a solution without phase separation and precipitation. Accordingly, the non-silicon multi-epoxy compound 412P was compatible with the modified particles. The solution was coated and baking cured (baked at 80° C. for 10 minutes and baked at 120° C. for 10 minutes) to form a dry film with a thickness of 5 micrometers. Accordingly, 412P could serve as the reactive compound.

0.25 g of a silicon-containing multi-epoxy compound DMS-EC13 (commercially available from Gelest, chemical structure of having a

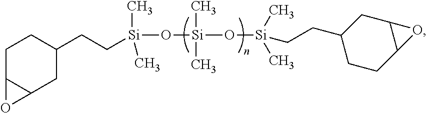

wherein n=1 to 6) and the dispersion containing 1 g of the modified particles in Synthesis Example 1 were blended to keep a solution without phase separation and precipitation. 0.25 g of a silicon-containing multi-epoxy compound DMS-EC13 and the dispersion containing 1 g of the modified particles in Synthesis Example 2 were blended to keep a solution without phase separation and precipitation. Accordingly, the silicon-containing multi-epoxy compound DMS-EC13 was compatible with the modified particles. The solution was coated and baking cured (baked at 80° C. for 10 minutes and baked at 120° ° C. for 10 minutes) to form a dry film with a thickness of 5 micrometers. Accordingly, DMS-EC13 could serve as the reactive compound. 0.25 g of a silicon-containing multi-epoxy compound ECMS-924 (commercially available from Gelest, having a chemical structure of

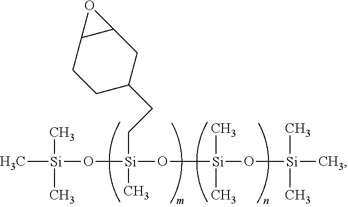

wherein m=1 to 6 and n=1 to 6) and the dispersion containing 1 g of the modified particles in Synthesis Example 1 were blended to generate phase separation or precipitation. Accordingly, the silicon-containing multi-epoxy compound ECMS-924 was not compatible with the modified particles. Accordingly, ECMS-924 could not serve as the reactive compound.

0.25 g of a silicon-containing multi-epoxy compound SIB-1110 (commercially available from Gelest, having a chemical structure of

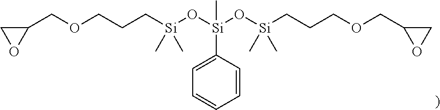 [SMILES: C[Si](C)(CCCOCC1CO1)O[Si](C)(O[Si](C)(C)CCCOCC1CO1)c1ccccc1]

and the dispersion containing 1 g of the modified particles in Synthesis Example 1 were blended to keep a solution without phase separation and precipitation. Accordingly, the silicon-containing multi-epoxy compound SIB-1110 was compatible with the modified particles. The solution was coated and baking cured (baked at 80° C. for 10 minutes and baked at 120° C. for 10 minutes) to form a dry film with a thickness of 5 micrometers. Accordingly, SIB-1110 could serve as the reactive compound.

0.25 g of a non-silicon multi-epoxy compound HDGE (1,6-hexanediol diglycidyl ether, commercially available from Aldrich, having a chemical structure of

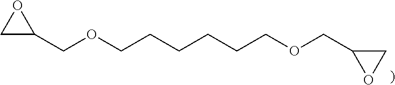 [SMILES: C(CCCOCC1CO1)CCOCC1CO1]

and the dispersion containing 1 g of the modified particles in Synthesis Example 1 were blended to keep a solution without phase separation and precipitation. Accordingly, the non-silicon multi-epoxy compound HDGE was compatible with the modified particles. The solution was coated and baking cured (baked at 80° ° C. for 10 minutes and baked at 120° C. for 10 minutes) to form a dry film with a thickness of 5 micrometers. Accordingly, HDGE could serve as the reactive compound.

0.25 g of a non-silicon multi-epoxy compound YL983U (commercially available from Mitsubishi Chemical Corporation, having a chemical structure of

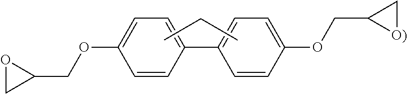

and the dispersion containing 1 g of the modified particles in Synthesis Example 1 were blended to keep a solution without phase separation and precipitation. Accordingly, the non-silicon multi-epoxy compound YL983U was compatible with the modified particles. The solution was coated and baking cured (baked at 80° C. for 10 minutes and baked at 120° C. for 10 minutes) to form a dry film with a thickness of 5 micrometers. Accordingly, YL983U could serve as the reactive compound.

0.25 g of a non-silicon multi-epoxy compound YL980 (commercially available from Mitsubishi Chemical Corporation, having a chemical structure of

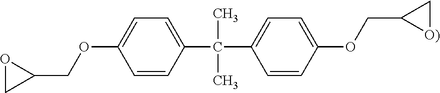

and the dispersion containing 1 g of the modified particles in Synthesis Example 1 were blended to keep a solution without phase separation and precipitation. Accordingly, the non-silicon multi-epoxy compound YL980 was compatible with the modified particles. The solution was coated and baking cured (baked at 80° ° C. for 10 minutes and baked at 120° C. for 10 minutes) to form a dry film with a thickness of 5 micrometers. Accordingly, YL980 could serve as the reactive compound. 0.25 g of a multi double-bond compound SR238 (commercially available from Sartomer AMERICAS, having a chemical structure of

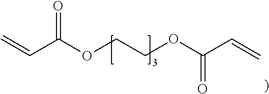

and the dispersion containing 1 g of the modified particles in Synthesis Example 1 were blended to keep a solution without phase separation and precipitation. Accordingly, the multi double-bond compound SR238 was compatible with the modified particles. The solution was coated and baking cured (baked at 80° C. for 10 minutes and baked at 120° C. for 10 minutes) to form a dry film with a thickness of 5 micrometers. Accordingly, SR238 could serve as the reactive compound.

0.25 g of a multi double-bond compound SR601 (commercially available from Sartomer AMERICAS, having a chemical structure of

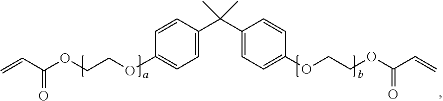

wherein a=2 to 6 and b=2 to 6) and the dispersion containing 1 g of the modified particles in Synthesis Example 1 were blended to keep a solution without phase separation and precipitation. Accordingly, the multi double-bond compound SR601 was compatible with the modified particles. The solution was coated and baking cured (baked at 80° C. for 10 minutes and baked at 120° C. for 10 minutes) to form a dry film with a thickness of 5 micrometers. Accordingly, SR601 could serve as the reactive compound.

### Example 1

The dispersion containing 8 parts by weight of the modified particles in Synthesis Example 1, 1 part by weight of the non-silicon multi-epoxy compound HDGE, and 1 part by weight of the silicon-containing multi-epoxy compound SIB-1110 were mixed, and 3 parts by weight of the solvent was then vacuumed out to form a solution having a viscosity of 30.3 cP at 25° ° C. to serve as a coating material. The coating material was blade coated to form a wet film with a thickness of 50 micrometers on a glass substrate. The wet film was baking cured (baked at 80° C. for 10 minutes and baked at 120° C. for 10 minutes) to form a coating layer with a thickness of 20 micrometers. The coating layer had a light-transmittance of 96.1%, a haze degree of 1.91 (Haze-Light Scattering Value), and a refractive index of 2.01 for a light having a wavelength of 550 nm.

### Example 2

The dispersion containing 7 parts by weight of the modified particles in Synthesis Example 1, 1.8 parts by weight of the non-silicon multi-epoxy compound HDGE, and 1.2 parts by weight of the silicon-containing multi-epoxy compound SIB-1110 were mixed, and 3 parts by weight of the solvent was then vacuumed out to form a solution having a viscosity of 35.6 cP at 25° C. to serve as a coating material. The coating material was blade coated to form a wet film with a thickness of 50 micrometers on a glass substrate. The wet film was baking cured (baked at 80° C. for 10 minutes and baked at 120° C. for 10 minutes) to form a coating layer with a thickness of 22 micrometers. The coating layer had a light-transmittance of 97.0%, a haze degree of 1.03 (Haze-Light Scattering Value), and a refractive index of 1.85 for a light having a wavelength of 550 nm. The coating layer had a light-transmittance change of less than or equal to 1.61% after being put at 110° C. for 500 hours.

### Example 3

The dispersion containing 7 parts by weight of the modified particles in Synthesis Example 1, 1.5 parts by weight of the non-silicon multi-epoxy compound HDGE, and 1.5 parts by weight of the silicon-containing multi-epoxy compound SIB-1110 were mixed, and 3 parts by weight of the solvent was then vacuumed out to form a solution having a viscosity of 32.3 cP at 25° C. to serve as a coating material. The coating material was blade coated to form a wet film with a thickness of 50 micrometers on a glass substrate. The wet film was baking cured (baked at 80° C. for 10 minutes and baked at 120° C. for 10 minutes) to form a coating layer with a thickness of 21 micrometers. The coating layer had a light-transmittance of 96.7%, a haze degree of 1.33 (Haze-Light Scattering Value), and a refractive index of 1.88 for a light having a wavelength of 550 nm.

### Example 4

The dispersion containing 6 parts by weight of the modified particles in Synthesis Example 1, 2 parts by weight of the non-silicon multi-epoxy compound HDGE, and 2 parts by weight of the silicon-containing multi-epoxy compound SIB-1110 were mixed, and 3 parts by weight of the solvent was then vacuumed out to form a solution having a viscosity of 41.0 cP at 25° ° C. to serve as a coating material. The coating material was blade coated to form a wet film with a thickness of 50 micrometers on a glass substrate. The wet film was baking cured (baked at 80° ° C. for 10 minutes and baked at 120° C. for 10 minutes) to form a coating layer with a thickness of 30 micrometers. The coating layer had a light-transmittance of 95.6%, a haze degree of 1.10 (Haze-Light Scattering Value), and a refractive index of 1.80 for a light having a wavelength of 550 nm.

### Example 5

The dispersion containing 7 parts by weight of the modified particles in Synthesis Example 3, 1.5 parts by weight of the non-silicon multi-epoxy compound HDGE, and 1.5 parts by weight of the silicon-containing multi-epoxy compound SIB-1110 were mixed, and 3 parts by weight of the solvent was then vacuumed out to form a solution having a viscosity of 5.1 cP at 25° ° C. to serve as a coating material. The coating material was blade coated to form a wet film with a thickness of 50 micrometers on a glass substrate. The wet film was baking cured (baked at 80° C. for 10 minutes and baked at 120° C. for 10 minutes) to form a coating layer with a thickness of 23 micrometers. The coating layer had a light-transmittance of 96.3%, a haze degree of 0.71 (Haze-Light Scattering Value), and a refractive index of 1.87 for a light having a wavelength of 550 nm.

### Example 6

The dispersion containing 5 parts by weight of the modified particles in Synthesis Example 1, 2.5 parts by weight of the non-silicon multi-epoxy compound HDGE, and 2.5 parts by weight of the silicon-containing multi-epoxy compound SIB-1110 were mixed, and 3 parts by weight of the solvent was then vacuumed out to form a solution having a viscosity of 48 cP at 25° C. to serve as a coating material. The coating material was blade coated to form a wet film with a thickness of 50 micrometers on a glass substrate. The wet film was baking cured (baked at 80° C. for 10 minutes and baked at 120° C. for 10 minutes) to form a coating layer with a thickness of 36 micrometers. The coating layer had a light-transmittance of 98.9%, a haze degree of 1.54 (Haze-Light Scattering Value), and a refractive index of 1.77 for a light having a wavelength of 550 nm.

### Comparative Example 1

The dispersion containing 9 parts by weight of the modified particles in Synthesis Example 1, 0.5 parts by weight of the non-silicon multi-epoxy compound HDGE, and 0.5 parts by weight of the silicon-containing multi-epoxy compound SIB-1110 were mixed, and 3 parts by weight of the solvent was then vacuumed out to form a coating material. The coating material was blade coated to form a wet film with a thickness of 50 micrometers on a glass substrate. The wet film was baking cured (baked at 80° C. for 10 minutes and baked at 120° C. for 10 minutes) to form a splitting coating layer.

### Comparative Example 2

The dispersion containing 7 parts by weight of the modified particles in Synthesis Example 1 and 3 parts by weight of the non-silicon multi-epoxy compound HDGE were mixed, and 3 parts by weight of the solvent was then vacuumed out to form a coating material. The coating material was blade coated to form a wet film with a thickness of 50 micrometers on a glass substrate. The wet film was baking cured (baked at 80° C. for 10 minutes and baked at 120° C. for 10 minutes) to form a coating layer. The coating layer had a light-transmittance less than 80%.

### Comparative Example 3

The dispersion containing 7 parts by weight of the modified particles in Synthesis Example 1, 2.4 parts by weight of the non-silicon multi-epoxy compound HDGE, and 0.6 parts by weight of the silicon-containing multi-epoxy compound SIB-1110 were mixed, and 3 parts by weight of the solvent was then vacuumed out to form a coating material. The coating material was blade coated to form a wet film with a thickness of 50 micrometers on a glass substrate. The wet film was baking cured (baked at 80° C. for 10 minutes and baked at 120° ° C. for 10 minutes) to form a coating layer. The coating layer had a light-transmittance less than 80%.

### Comparative Example 4

The dispersion containing 7 parts by weight of the modified particles in Synthesis Example 1, 1.2 parts by weight of the non-silicon multi-epoxy compound HDGE, and 1.8 parts by weight of the silicon-containing multi-epoxy compound SIB-1110 were mixed, and 3 parts by weight of the solvent was then vacuumed out to form a coating material. The coating material was blade coated to form a wet film with a thickness of 50 micrometers on a glass substrate. The wet film was baking cured (baked at 80° C. for 10 minutes and baked at 120° ° C. for 10 minutes) to form a coating layer. The coating layer was split after being put at room temperature for a period of time.

### Comparative Example 5

The dispersion containing 7 parts by weight of the modified particles in Synthesis Example 1, 0.6 parts by weight of the non-silicon multi-epoxy compound HDGE, and 2.4 parts by weight of the silicon-containing multi-epoxy compound SIB-1110 were mixed, and 3 parts by weight of the solvent was then vacuumed out to form a coating material. The coating material was blade coated to form a wet film with a thickness of 50 micrometers on a glass substrate. The wet film was baking cured (baked at 80° C. for 10 minutes and baked at 120° C. for 10 minutes) to form a coating layer. The coating layer was split after being put at room temperature for a period of time.

### Comparative Example 6

The dispersion containing 7 parts by weight of the modified particles in Synthesis Example 1 and 3 parts by weight of the silicon-containing multi-epoxy compound SIB-1110 were mixed, and 3 parts by weight of the solvent was then vacuumed out to form a coating material. The coating material was blade coated to form a wet film with a thickness of 50 micrometers on a glass substrate. The wet film was baking cured (baked at 80° C. for 10 minutes and baked at 120° C. for 10 minutes) to form a coating layer. The coating layer was split after being put at room temperature for a period of time.

### Comparative Example 7

The dispersion containing 7 parts by weight of the core particles (without modification) in Synthesis Example 1, 1.5 parts by weight of the non-silicon multi-epoxy compound HDGE, and 1.5 parts by weight of the silicon-containing multi-epoxy compound SIB-1110 were mixed, and 3 parts by weight of the solvent was then vacuumed out to form a coating material. The coating material was blade coated to form a wet film with a thickness of 50 micrometers on a glass substrate. The wet film was baking cured (baked at 80° C. for 10 minutes and baked at 120° C. for 10 minutes) to form a splitting coating layer.

### Example 7

The dispersion containing 8 parts by weight of the modified particles in Synthesis Example 4, 2 parts by weight of the multi double-bond compound SR238, and 0.01 parts by weight of an initiator azobisisobutyronitrile (AIBN) were mixed, and 3 parts by weight of the solvent was then vacuumed out to form a solution having a viscosity of 6.8 cP at 25° C. to serve as a coating material. The coating material was blade coated to form a wet film with a thickness of 50 micrometers on a glass substrate. The wet film was baking cured (baked at 80° ° C. for 10 minutes) and then UV cured (1500 J/cm² for 1 minute) to form a coating layer with a thickness of 21 micrometers. The coating layer had a light-transmittance of 95.8%, a haze degree of 1.91 (Haze-Light Scattering Value), and a refractive index of 1.88 for a light having a wavelength of 550 nm.

### Example 8

The dispersion containing 7 parts by weight of the modified particles in Synthesis Example 4, 3 parts by weight of the multi double-bond compound SR238, and 0.01 parts by weight of an initiator AIBN were mixed, and 3 parts by weight of the solvent was then vacuumed out to form a solution having a viscosity of 5.9 cP at 25° C. to serve as a coating material. The coating material was blade coated to form a wet film with a thickness of 50 micrometers on a glass substrate. The wet film was baking cured (baked at 80° C. for 10 minutes) and then UV cured (1500 J/cm² for 1 minute) to form a coating layer with a thickness of 22 micrometers. The coating layer had a light-transmittance of 96.3%, a haze degree of 1.82 (Haze-Light Scattering Value), and a refractive index of 1.82 for a light having a wavelength of 550 nm.

### Example 9

The dispersion containing 6 parts by weight of the modified particles in Synthesis Example 4, 4 parts by weight of the multi double-bond compound SR238, and 0.01 parts by weight of an initiator AIBN were mixed, and 3 parts by weight of the solvent was then vacuumed out to form a solution having a viscosity of 6.5 cP at 25° C. to serve as a coating material. The coating material was blade coated to form a wet film with a thickness of 50 micrometers on a glass substrate. The wet film was baking cured (baked at 80° C. for 10 minutes) and then UV cured (1500 J/cm² for 1 minute) to form a coating layer with a thickness of 23 micrometers. The coating layer had a light-transmittance of 96.9%, a haze degree of 1.72 (Haze-Light Scattering Value), and a refractive index of 1.80 for a light having a wavelength of 550 nm.

### Example 10

The dispersion containing 5 parts by weight of the modified particles in Synthesis Example 4, 5 parts by weight of the multi double-bond compound SR238, and 0.01 parts by weight of an initiator AIBN were mixed, and 3 parts by weight of the solvent was then vacuumed out to form a solution having a viscosity of 6.1 cP at 25° C. to serve as a coating material. The coating material was blade coated to form a wet film with a thickness of 50 micrometers on a glass substrate. The wet film was baking cured (baked at 80° C. for 10 minutes) and then UV cured (1500 J/cm² for 1 minute) to form a coating layer with a thickness of 23 micrometers. The coating layer had a light-transmittance of 98.2%, a haze degree of 1.4 (Haze-Light Scattering Value), and a refractive index of 1.75 for a light having a wavelength of 550 nm.

### Comparative Example 8

The dispersion containing 9 parts by weight of the modified particles in Synthesis Example 4, 1 part by weight of the multi double-bond compound SR238, and 0.01 parts by weight of an initiator AIBN were mixed, and 3 parts by weight of the solvent was then vacuumed out to form a coating material. The coating material was blade coated to form a wet film with a thickness of 50 micrometers on a glass substrate. The wet film was baking cured (baked at 80° C. for 10 minutes) and then UV cured (1500 J/cm² for 1 minute) to form a splitting coating layer.

### Example 11

The dispersion containing 8 parts by weight of the modified particles in Synthesis Example 5, 1.5 part by weight of the non-silicon multi-epoxy compound HDGE, and 1.5 part by weight of the silicon-containing multi-epoxy compound SIB-1110 were mixed, and 3 parts by weight of the solvent was then vacuumed out to form a solution having a viscosity of 46.7 cP at 25° ° C. to serve as a coating material. The coating material was blade coated to form a wet film with a thickness of 50 micrometers on a glass substrate. The wet film was baking cured (baked at 80° C. for 10 minutes and baked at 120° C. for 10 minutes) to form a coating layer with a thickness of 25 micrometers. The coating layer had a light-transmittance of 97.1%, a haze degree of 0.47 (Haze-Light Scattering Value), and a refractive index of 1.82 for a light having a wavelength of 550 nm.

It will be apparent to those skilled in the art that various modifications and variations can be made to the disclosed methods and materials. It is intended that the specification and examples be considered as exemplary only, with the true scope of the disclosure being indicated by the following claims and their equivalents.

What is claimed is:

1. A coating material, comprising:
a modified particle, including:
a core; and
a silane coupling agent having an epoxy group or a silane coupling agent having a double-bond grafted onto a surface of the core;
wherein the core includes (1) an oxide of zinc and titanium, and zinc and titanium have a weight ratio of 1:0.4 to 1:0.9, (2) an oxide of zirconium and titanium, and zirconium and titanium have a weight ratio of 1:0.1 to 1:2, or (3) an oxide of zinc and zirconium, and zinc and zirconium have a weight ratio of 1:0.8 to 1:2; and
a reactive compound,
when the silane coupling agent having the epoxy group is grafted onto the surface of the core, the reactive compound includes a non-silicon multi-epoxy compound and a silicon-containing multi-epoxy compound,
when the silane coupling agent having the double-bond is grafted onto the surface of the core, the reactive compound includes a multi double-bond compound.

2. The coating material as claimed in claim 1, wherein the total weight of zinc and titanium, the total weight of zirconium and titanium, or the total weight of zinc and 2 zirconium in the core and a weight of the silane coupling agent having the epoxy group or the silane coupling agent having the double-bond have a ratio of 1:0.1 to 1:3.

3. The coating material as claimed in claim 1, wherein the core has an average diameter of 10 nm to 120 nm.

4. The coating material as claimed in claim 1, wherein the silane coupling agent having the epoxy group comprises (3-glycidyloxypropyl)trimethoxysilane, (3-glycidyloxypropyl)triethoxysilane, (3-glycidyloxypropyl)dimethoxymethylsilane, (3-glycidyloxypropyl)diethoxymethylsilane, β-(3,4-epoxycyclohexane)ethyl trimethoxysilane, or β-(3,4-epoxycyclohexane)ethyltriethoxysilane.

5. The coating material as claimed in claim 1, wherein the silane coupling agent having the double-bond comprises 3-(trimethoxysilyl)propyl acrylate, 3-isocyanatopropyltriethoxysilane, or 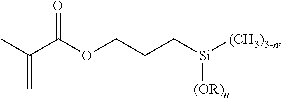
wherein R is methyl or ethyl, and n is 1-3.

6. The coating material as claimed in claim 1, wherein the core and the reactive compound have a weight ratio of 1:0.2 to 1:0.8.

7. The coating material as claimed in claim 1, wherein the non-silicon multi-epoxy compound and the silicon-containing multi-epoxy compound have a weight ratio of 1:0.4 to 1:1.

8. The coating material as claimed in claim 1, wherein the non-silicon multi-epoxy compound includes a long carbon chain, a benzene ring, or a cyclic structure, and the non-silicon multi-epoxy compound has a viscosity of less than 1000 cP at 25° C.

9. The coating material as claimed in claim 1, wherein the non-silicon multi-epoxy compound comprises 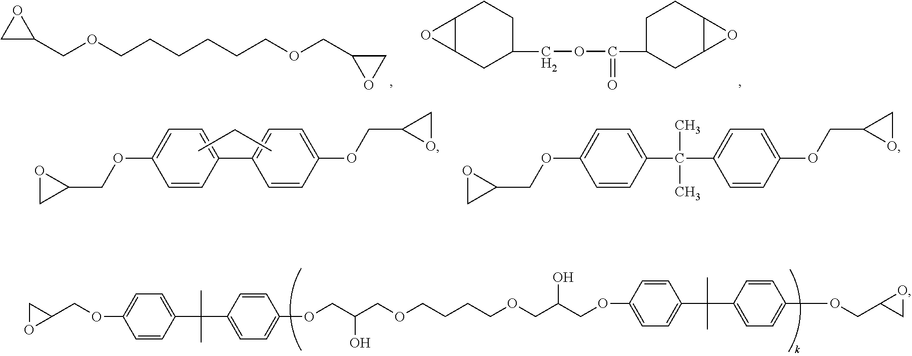
wherein k=1 to 6, or a combination thereof.

10. The coating material as claimed in claim 1, wherein the silicon-containing multi-epoxy compound includes a long carbon chain, a benzene ring, or a cyclic structure, and the silicon-containing multi-epoxy compound has a viscosity of less than 1000 cP at 25° C.

11. The coating material as claimed in claim 1, wherein the silicon-containing multi-epoxy compound comprises 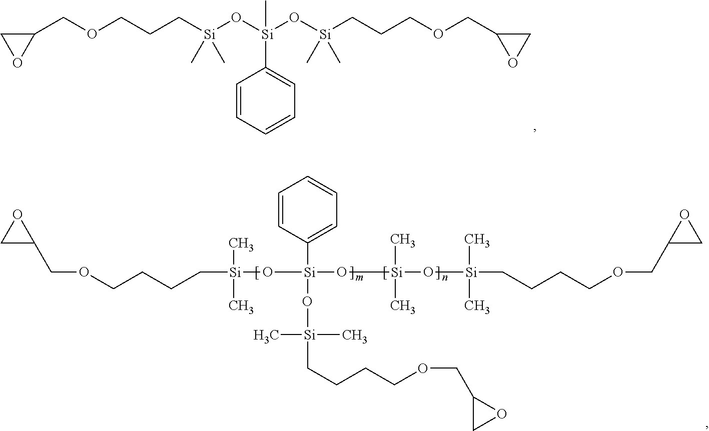
wherein m=1 to 6 and n=1 to 6, 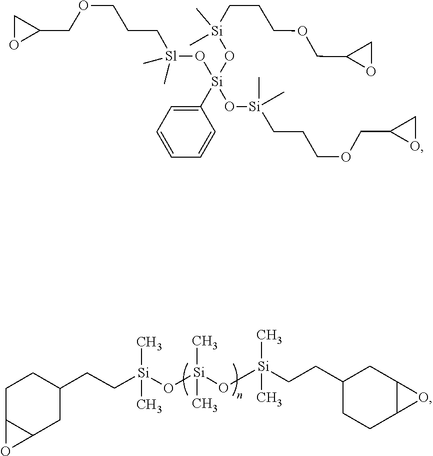
wherein n=1 to 6, or a combination thereof.

12. The coating material as claimed in claim 1, wherein the multi double-bond compound includes a long carbon chain, a benzene ring, or a cyclic structure, and the multi double-bond compound has a viscosity of less than 1000 cP at 25° C.

13. The coating material as claimed in claim 1, wherein the multi double-bond compound comprises 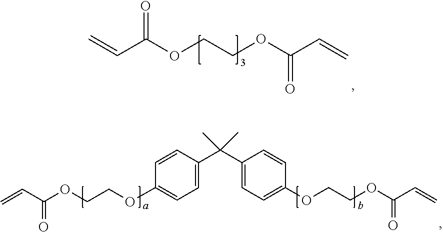
wherein a=2 to 6 and b=2 to 6, or a combination thereof.

14. A coating layer, formed by reacting the coating material as claimed in claim 1.

15. The coating layer as claimed in claim 14, wherein the coating layer has a thickness of 20 micrometers to 40 micrometers, a refractive index of 1.7 to 2.4, and a light-transmittance of 90% to 99.5%.

16. A light-emitting device, comprising:
a substrate;
a light-emitting element disposed on the substrate; and
the coating layer as claimed in claim 14 covering the substrate and the light-emitting element.

17. The light-emitting device as claimed in claim 16, wherein the coating layer has a thickness of 20 micrometers to 40 micrometers, a refractive index of 1.7 to 2.4, and a light-transmittance of 90% to 99.5%.
